(19) United States
(12) Patent Application Publication
(10) Pub. No.: US 2014/0131091 A1
(43) Pub. Date: May 15, 2014

(54) PHASE TRANSFORMATION COATING FOR IMPROVED SCRATCH RESISTANCE

(71) Applicant: Nicholas James Smith, Horseheads, NY (US)

(72) Inventor: Nicholas James Smith, Horseheads, NY (US)

(21) Appl. No.: 13/673,131

(22) Filed: Nov. 9, 2012

(51) Int. Cl. C03C 17/22; H05K 5/03; C03C 17/23

(52) U.S. Cl. CPC C03C 17/22; C03C 17/23; H05K 5/03
USPC 174/565; 428/432; 428/336; 428/220

(57) ABSTRACT

A scratch-resistant glass substrate is prepared by forming a phase-transformable, scratch-resistant layer over a major surface of the substrate. The phase-transformable layer can comprise the metastable, tetragonal polymorph of zirconium oxide. Under the application of an applied scratch, such as during a scratch event, the tetragonal phase can undergo a phase-transformation and concomitant volume expansion to the monoclinic phase. The volume expansion can reduce and soften the physical dimensions of the scratch, which can make the scratch less visible.

### BACKGROUND

The present disclosure relates generally to surface-modified glass substrates, and more particularly to glass substrates having a scratch-resistant layer provided over a major surface of the substrate. The scratch-resistant layer can undergo a local phase transformation and exhibit a concomitant local volume expansion in response to a scratch event.

Scratches are a concern for glass cover applications in hand held devices and other devices such as monitors and other displays. Scratches increase the scattering of light and can reduce the brightness and contrast of images and text that is presented on such screens. In the device-off state, for example, scratches can make the display look hazy, marred and unattractive. In particular for displays and handheld devices, scratch resistance can be an important attribute. A scratch is the mark that may be formed in a surface from mechanical contact of the surface with a sharp implement, where the force inducing the mechanical contact typically includes both a perpendicular component that drives the implement into the surface and a parallel, dragging force that translates the implement over the surface to some length. The length of a scratch is somewhat arbitrary and is not a useful description of the scratch in terms of material response. Scratches can be infinitely long, or can essentially be a simple symmetric indent into a surface without a definable length.

Scratches can be characterized by their depth as well as their width. Deep scratches extend at least 2 microns into the surface of the material, and wide scratches are more than 2 microns wide. Due to the physical extent of the scratch, fragmentation or chipping typically accompanies deep and/or wide scratches. In brittle solids, though, such as glass substrates, the resistance to deep and wide scratches can be improved through optimization of glass chemistry, i.e., glass composition.

On the other hand, scratches can also be shallow and/or narrow. Shallow scratches are characterized by a depth of less than 2 microns, and narrow scratches are characterized by a width of less than 2 microns. Scratches at these dimensional scales are sometimes described as “microductile” scratches, where the inherent material response even in brittle materials like glass possesses some degree of ductility, i.e., permanent deformation, rather than a fully-elastic response. In displays and handheld devices, where a glass cover can be formed from an oxide glass, a large fraction of the scratches accumulated during use are believed to be microductile scratches. Though microductile scratches are not typically associated with large volumes of fragmented or chipped material, microductile scratches can adversely affect the optical properties of a glass cover. Further, in contrast to the larger, “heavy” scratches, microductile scratches are not easily prevented through modification of the glass chemistry.

The formation of microductile scratches can be attenuated by adjusting the hardness or modulus of the surface that is being scratched. Hardness is a measure of the resistance of a material to deformation, and is one material property that can benefit scratch resistance. Harder surfaces typically are more resistant to microductile scratching. While oxide glasses that form the glass substrates used in many glass covers typically have hardness values in the range of 6 to 9 GPa, as disclosed herein, the propensity of microductile scratch formation can be dramatically decreased by forming a harder surface layer on the oxide glass. The elastic modulus of a material considers the amount of stress built up under deformation. Diamond-like carbon (DLC) coatings, for example, are valued for scratch-resistance due to both their high hardness and low elastic modulus, leading to an especially significant degree of elastic recovery during a scratch event.

In view of the foregoing, it would be desirable to provide a hard, optically-transparent, scratch-resistant layer that can be provided on a rigid glass cover that is economical, and physically and chemically compatible with the underlying glass. Such a scratch-resistant layer can minimize the formation of scratches and, in some embodiments, minimize the visibility of scratches that do form.

### SUMMARY

Disclosed herein is a glass substrate having a modified surface. The glass substrate includes a glass main body having opposing major surfaces, and a layer formed over one of the major surfaces that exhibits a stress-induced phase transformation. The layer can be a phase-transformation layer and can comprise a phase-transformable material such as zirconium oxide in its tetragonal polymorph. In response to a scratch event, the stress applied to tetragonal zirconium oxide can induce a phase transformation to the monoclinic polymorph. For zirconium oxide, a 3 to 5% volume expansion accompanies the tetragonal-to-monoclinic transformation. Adjacent to a free surface, this volume expansion may cause some of the material within the deformed zone of the scratch to expand outward and, in effect, partially heal the scratched region and cause the scratch to be less visible.

The surface-modified glass substrate can be used as cover glass or as part of the housing for an electronic device where the phase-transformable layer is provided as the outward-facing layer. For instance, in an electronic device housing, the glass substrate can form at least part of (a) a front glass cover that is placed and secured to provide a front surface for the electronic device enclosure, and/or (b) a back glass cover that is placed and secured to provide a back surface for the electronic device enclosure. One or both of the front glass cover and the back glass cover can also be shaped to extend to a side of the housing to provide a side surface for the enclosure.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description present embodiments of the invention, and are intended to provide an overview or framework for understanding the nature and character of the invention as it is claimed. The accompanying drawings are included to provide a further understanding of the invention, and are incorporated into and constitute a part of this specification. The drawings illustrate various embodiments of the invention and together with the description serve to explain the principles and operations of the invention.

### BRIEF DESCRIPTION OF THE DRAWINGS

FIG. 1 is a schematic of a layer provided over a major surface of a glass substrate;

FIG. 2 is a schematic diagram of a single chamber sputter tool for forming layers on glass substrates according to some embodiments;

FIG. 3 is a graphic showing a crack-tip in a phase-transformation material;

FIG. 4 is a plot of material displacement versus distance for the crack-tip model of FIG. 3;

FIG. 5 is a schematic showing scratch formation in a glass surface under a monotonic loading cycle;

FIG. 6 shows scratch formation and elastic recovery for various glass samples;

FIG. 7 is a top view of a mobile electronic device having a cover plate formed of a scratch-resistant glass according to various embodiments; and

FIG. 8 is a view of an electronic device structure according to various embodiments.

### DETAILED DESCRIPTION

A glass article comprises a glass main body having opposing major surfaces, and a layer provided over a majority of a first major surface. The layer, which may provide scratch-resistance to the underlying glass, comprises a stress-induced, phase-transformation material. The phase-transformation layer is resistant to scratching and, in addition, exhibits a volumetric expansion concomitant with a scratch-induced phase-transformation that minimizes the appearance or visibility of any deformation that does occur.

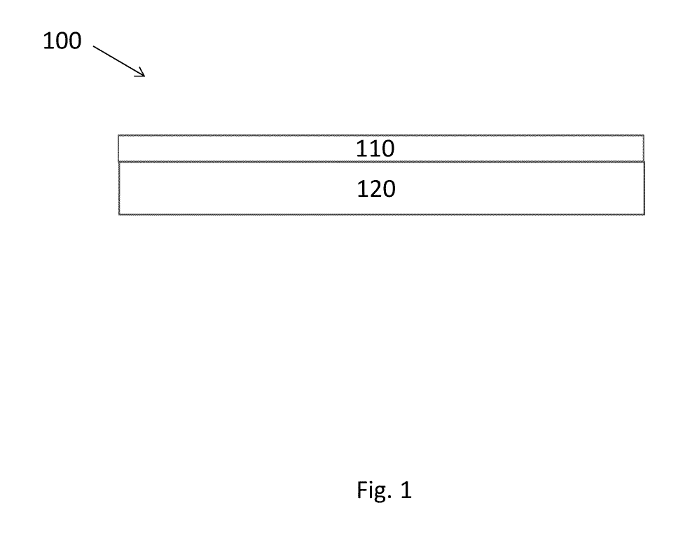

The phase-transformable layer may comprise an optically-transparent hard coat that imparts scratch-resistance to the glass substrate. In embodiments, the glass substrate comprises chemically-strengthened glass. The phase-transformable layer can substantially enhance the scratch resistance of a surface of the substrate while maintaining the overall optical clarity of the glass. A scratch-resistant glass substrate 100 comprising a phase-transformation layer 110 provided over a major surface of a glass main body 120 is shown schematically in FIG. 1. The phase-transformation layer can be a contiguous layer that covers a major surface of the glass substrate.

The glass substrate itself may be provided using a variety of different processes. For instance, example glass substrate forming methods include float processes and down-draw processes such as fusion draw, slot draw and roll forming

In the float glass method, a sheet of glass that may be characterized by smooth surfaces and uniform thickness is made by floating molten glass on a bed of molten metal, typically tin. In an example process, molten glass that is fed onto the surface of the molten tin bed forms a floating ribbon. As the glass ribbon flows along the tin bath, the temperature is gradually decreased until a solid glass sheet can be lifted from the tin onto rollers. Once off the bath, the glass sheet can be cooled further and annealed to reduce internal stress.

Down-draw processes produce glass sheets having a uniform thickness that possess surfaces that are relatively pristine. Because the strength of the glass surface is controlled by the amount and size of surface flaws, a pristine surface that has had minimal contact has a higher initial strength. When this high strength glass is then chemically-strengthened, the resultant strength can be higher than that of a surface that has been a lapped and polished. Down-drawn glass may be drawn to a thickness of less than about 2 mm. In addition, down drawn glass has a very flat, smooth surface that can be used in its final application without costly grinding and polishing.

The fusion draw process, for example, uses a drawing tank that has a channel for accepting molten glass raw material. The channel has weirs that are open at the top along the length of the channel on both sides of the channel. When the channel fills with molten material, the molten glass overflows the weirs. Due to gravity, the molten glass flows down the outside surfaces of the drawing tank. These outside surfaces extend down and inwardly so that they join at an edge below the drawing tank. The two flowing glass surfaces join at this edge to fuse and form a single flowing sheet. The fusion draw method offers the advantage that, because the two glass films flowing over the channel fuse together, neither outside surface of the resulting glass sheet comes in contact with any part of the apparatus. Thus, the surface properties of the fusion drawn glass sheet are not affected by such contact.

The slot draw method is distinct from the fusion draw method. Here the molten raw material glass is provided to a drawing tank. The bottom of the drawing tank has an open slot with a nozzle that extends the length of the slot. The molten glass flows through the slot/nozzle and is drawn downward as a continuous sheet and into an annealing region. The slot draw process can provide a thinner sheet than the fusion draw process because only a single sheet is drawn through the slot, rather than two sheets being fused together.

The glass substrate, in some embodiments, may be batched with 0-2 mol. % of at least one fining agent selected from a group that includes Na₂SO₄, NaCl, NaF, NaBr, K₂SO₄, KCl, KF, KBr, and SnO₂.

Once formed, glass substrates may be chemically strengthened by an ion exchange process. In this process, typically by immersion of the glass substrate into a molten salt bath for a predetermined period of time, ions at or near the surface of the glass are exchanged for larger metal ions from the salt bath. In one embodiment, the temperature of the molten salt bath is about 430° C. and the predetermined time period is about eight hours. The incorporation of the larger ions into the glass strengthens the substrate by creating a compressive stress in a near surface region. A corresponding tensile stress is induced within a central region of the glass to balance the compressive stress.

In one example embodiment, sodium ions in the chemically-strengthened glass can be replaced by potassium ions from the molten bath, though other alkali metal ions having larger atomic radii, such as rubidium or cesium, can replace smaller alkali metal ions in the glass. According to particular embodiments, smaller alkali metal ions in the glass can be replaced by Ag⁺ ions. Similarly, other alkali metal salts such as, but not limited to, sulfates, halides, and the like may be used in the ion exchange process.

The replacement of smaller ions by larger ions at a temperature below that at which the glass network can relax produces a distribution of ions across the surface of the glass that results in a stress profile. The larger volume of the incoming ion produces a compressive stress (CS) on the surface and tension (central tension, or CT) in the center of the glass. The compressive stress is related to the central tension by the following relationship:

$$CS = CT ( \frac{t - 2 DOL}{DOL} )$$

where t is the total thickness of the glass sheet and DOL is the depth of ion exchange, also referred to as depth of layer.

In one embodiment, a chemically-strengthened glass sheet can have a surface compressive stress of at least 300 MPa, e.g., at least 400, 450, 500, 550, 600, 650, 700, 750 or 800 MPa, a depth of layer at least about 20 μm (e.g., at least about 20, 25, 30, 35, 40, 45, or 50 μm) and/or a central tension greater than 40 MPa (e.g., greater than 40, 45, or 50 MPa) but less than 100 MPa (e.g., less than 100, 95, 90, 85, 80, 75, 70, 65, 60, or 55 MPa).

Example ion-exchangeable glasses that may be used as the glass substrate are alkali aluminosilicate glasses or alkali aluminoborosilicate glasses, though other glass compositions are contemplated. As used herein, “ion exchangeable” means that a glass is capable of exchanging cations located at or near the surface of the glass with cations of the same valence that are either larger or smaller in size.

One example glass composition comprises SiO₂, B₂O₃ and Na₂O, where (SiO₂+B₂O₃)≧66 mol. %, and Na₂O≧9 mol. %. In an embodiment, the glass substrate includes at least 6 wt. % aluminum oxide. In a further embodiment, a glass substrate includes one or more alkaline earth oxides, such that a content of alkaline earth oxides is at least 5 wt. %. Suitable glass compositions, in some embodiments, further comprise at least one of K₂O, MgO, and CaO. In a particular embodiment, the glass substrate can comprise 61-75 mol. % SiO₂; 7-15 mol. % Al₂O₃; 0-12 mol. % B₂O₃; 9-21 mol. % Na₂O; 0-4 mol. % K₂O; 0-7 mol. % MgO; and 0-3 mol. % CaO.

A further example glass composition suitable for the glass substrate comprises: 60-70 mol. % SiO₂; 6-14 mol. % Al₂O₃; 0-15 mol. % B₂O₃; 0-15 mol. % Li₂O; 0-20 mol. % Na₂O; 0-10 mol. % K₂O; 0-8 mol. % MgO; 0-10 mol. % CaO; 0-5 mol. % ZrO₂; 0-1 mol. % SnO₂; 0-1 mol. % CeO₂; less than 50 ppm As₂O₃; and less than 50 ppm SbO₂O₃; where 12 mol. %≦(Li₂O+Na₂O+K₂O)≦20 mol. % and 0 mol. %≦(MgO+CaO)≦10 mol. %.

A still further example glass composition comprises: 63.5-66.5 mol. % SiO₂; 8-12 mol. % Al₂O₃; 0-3 mol. % B₂O₃; 0-5 mol. % Li₂O; 8-18 mol. % Na₂O; 0-5 mol. % K₂O; 1-7 mol. % MgO; 0-2.5 mol. % CaO; 0-3 mol. % ZrO₂; 0.05-0.25 mol. % SnO₂; 0.05-0.5 mol. % CeO₂; less than 50 ppm As₂O₃; and less than 50 ppm Sb₂O₃; where 14 mol. %≦(Li₂O+Na₂O+K₂O)≦18 mol. % and 2 mol. %≦(MgO+CaO)≦7 mol. %.

In a particular embodiment, an alkali aluminosilicate glass comprises alumina, at least one alkali metal and, in some embodiments, greater than 50 mol. % SiO₂, in other embodiments at least 58 mol. % SiO₂, and in still other embodiments at least 60 mol. % SiO₂, wherein the ratio

$$\frac{{Al}_{2} {O}_{3} + {B}_{2} {O}_{3}}{\sum modifiers} > 1 ,$$

where in the ratio the components are expressed in mol. % and the modifiers are alkali metal oxides. This glass, in particular embodiments, comprises, consists essentially of, or consists of: 58-72 mol. % SiO₂; 9-17 mol. % Al₂O₃; 2-12 mol. % B₂O₃; 8-16 mol. % Na₂O; and 0-4 mol. % K₂O, wherein the ratio

$$\frac{{Al}_{2} {O}_{3} + {B}_{2} {O}_{3}}{\sum modifiers} > 1.$$

In another embodiment, an alkali aluminosilicate glass comprises, consists essentially of, or consists of: 61-75 mol. % SiO₂; 7-15 mol. % Al₂O₃; 0-12 mol. % B₂O₃; 9-21 mol. % Na₂O; 0-4 mol. % K₂O; 0-7 mol. % MgO; and 0-3 mol. % CaO.

In yet another embodiment, an alkali aluminosilicate glass substrate comprises, consists essentially of, or consists of: 60-70 mol. % SiO₂; 6-14 mol. % Al₂O₃; 0-15 mol. % B₂O₃; 0-15 mol. % Li₂O; 0-20 mol. % Na₂O; 0-10 mol. % K₂O; 0-8 mol. % MgO; 0-10 mol. % CaO; 0-5 mol. % ZrO₂; 0-1 mol. % SnO₂; 0-1 mol. % CeO₂; less than 50 ppm As₂O₃; and less than 50 ppm Sb₂O₃; wherein 12 mol. %≦Li₂O+Na₂O+K₂O≦20 mol. % and 0 mol. %≦MgO+CaO≦10 mol. %.

In still another embodiment, an alkali aluminosilicate glass comprises, consists essentially of, or consists of: 64-68 mol. % SiO₂; 12-16 mol. % Na₂O; 8-12 mol. % Al₂O₃; 0-3 mol. % B₂O₃; 2-5 mol. % K₂O; 4-6 mol. % MgO; and 0-5 mol. % CaO, wherein: 66 mol. %≦SiO₂+B₂O₃+CaO≦69 mol. %; Na₂O+K₂O+B₂O₃+MgO+CaO+SrO>10 mol. %; 5 mol. %≦MgO+CaO+SrO≦8 mol. %; (Na₂O+B₂O₃)—Al₂O₃≦2 mol. %; 2 mol. %≦Na₂O—Al₂O₃≦6 mol. %; and 4 mol. %≦(Na₂O+K₂O)—Al₂O₃≦10 mol. %.

The glass substrate can have a thickness ranging from about 100 microns to 5 mm. Example substrate thicknesses range from 100 microns to 500 microns, e.g., 100, 200, 300, 400 or 500 microns. Further example substrate thicknesses range from 500 microns to 1000 microns, e.g., 500, 600, 700, 800, 900 or 1000 microns. The glass substrate may have a thickness greater than 1 mm, e.g., about 2, 3, 4, or 5 mm.

The phase-transformation layer can be formed by chemical vapor deposition (e.g., plasma enhanced chemical vapor deposition), physical vapor deposition (e.g., sputter deposition or laser ablation) or thermal evaporation of a suitable starting material directly onto a glass substrate or onto a previously surface-modified glass substrate.

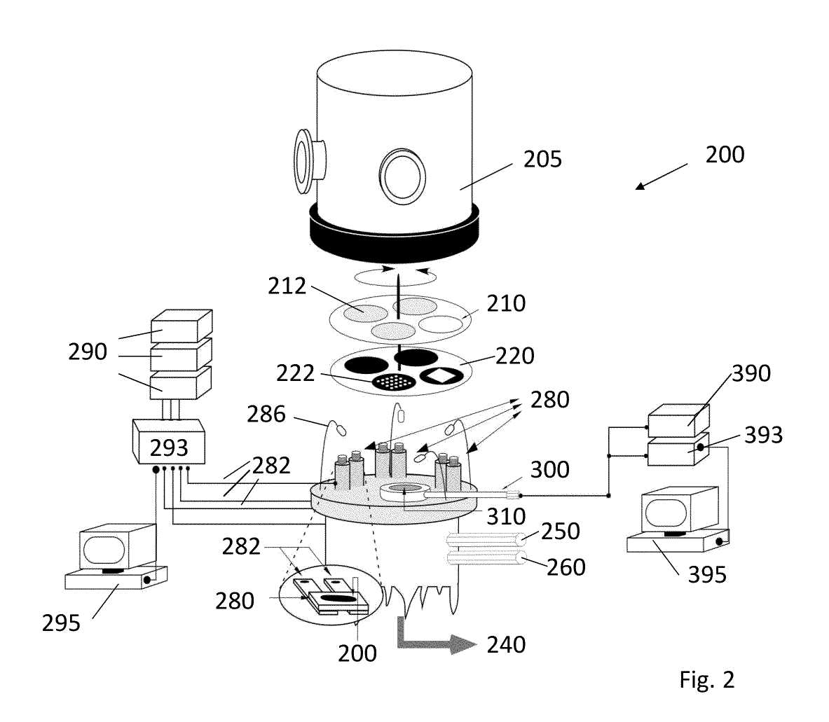

Sputtering processes may include reactive sputtering or non-reactive sputtering. A single-chamber sputter deposition apparatus 200 for forming such phase-transformation layers is illustrated schematically in FIG. 2. The apparatus 200 includes a vacuum chamber 205 having a substrate stage 210 onto which one or more glass substrates 212 can be mounted, and a mask stage 220, which can be used to mount shadow masks 222 for patterned deposition of a layer onto a defined region of a substrate. The chamber 205 is equipped with a vacuum port 240 for controlling the interior pressure, as well as a water cooling port 250 and a gas inlet port 260. The vacuum chamber can be cryo-pumped (CTI-8200/Helix; MA, USA) and is capable of operating at pressures suitable for both evaporation processes (˜10⁻⁶ Torr) and RF sputter deposition processes (˜10⁻³ Torr).

As shown in FIG. 2, multiple evaporation fixtures 280, each having an optional corresponding shadow mask 222 for evaporating material onto a glass substrate 212 are connected via conductive leads 282 to a respective power supply 290. A starting material 200 to be evaporated can be placed into each fixture 280. Thickness monitors 286 can be integrated into a feedback control loop including a controller 293 and a control station 295 in order to affect control of the amount of material deposited.

In an example system, each of the evaporation fixtures 280 are outfitted with a pair of copper leads 282 to provide DC current at an operational power of about 80-180 Watts. The effective fixture resistance will generally be a function of its geometry, which will determine the precise current and wattage. In embodiments, the phase-transformation layer can be deposited under an applied bias, which can affect the size of crystallites in the layer and therefore strongly favor the desired metastable crystal phase. Example sputter conditions to achieve the tetragonal phase in a zirconia film are a base pressure below 5×10⁻⁷ torr, a 10 mtorr working pressure, a mass flow ratio of argon to oxygen of about 1.6, a substrate DC bias from 0 to 850 V, and a power density of about 13.2 W/cm².

An RF sputter gun 300 having a sputter target 310 is also provided for forming a layer of material (e.g., metal oxide, nitride, carbide or boride) on a glass substrate. The RF sputter gun 300 is connected to a control station 395 via an RF power supply 390 and feedback controller 393. To form the phase-transformation layer by sputtering, a water-cooled cylindrical RF sputtering gun (Onyx-3™, Angstrom Sciences, Pa) can be positioned within the chamber 105. Suitable RF deposition conditions include 50-150 W forward power (<1 W reflected power), which corresponds to a typical deposition rate of about ˜5 Å/second (Advanced Energy, Co, USA). In embodiments, the sputtering rate can vary between 0.1 and 10 angstroms per second, for example.

In embodiments where the glass substrate is a chemically-strengthened glass substrate, in order to not adversely affect the stress profile within the substrate, the act of forming a phase-transformation layer over a surface of the substrate comprises heating the glass substrate to a maximum temperature of 500° C. The temperature of the substrate during the act of providing the phase-transformation layer can range from about −200° C. to 500° C. In embodiments, the substrate temperature is maintained at a temperature between about room temperature and 500° C., e.g., at a temperature of less than 500° C. or less than 300° C. during the formation of the phase-transformation layer. Such relatively-low temperature processing may be used to preserve the dimensional attributes of the glass substrate and, in the example of a chemically-strengthened glass substrate, the ion-exchange profile.

A phase-transformation layer is any layer that undergoes a stress-induced phase transformation in the region proximate to the applied stress. Such a stress-induced phase transformation may be referred to as a martensitic phase transformation. Compositionally, the phase-transformation layer may comprise a metal oxide layer. An example metal oxide is zirconium oxide. Other materials that have been identified as exhibiting similar transformations include calcium disilicate, refractory sulfides, and the lanthanide sesquioxides, each with specific target phases that exhibit the desired stress-induced transformation behavior and accompanying volume expansion. A summary of phase-transformation layer materials is provided in Table 1. As used herein, the symbol “Ln” is used as an abbreviation for a lanthanide element.

TABLE 1
Example phase-transformation materials

| Compound | Stress-induced transformation | ΔV (%) |
|---|---|---|
| ZrO₂ | tetragonal → monoclinic | 4.9% |
| Ln₂O₃ | monoclinic → cubic | 8-10% |
| 2CaO•SiO₂ | monoclinic → orthorhombic | 12 |
| NiS | rhombohedral → hexagonal | 4 |
| LuBO₃ | hexagonal → rhombohedral | 8 |

In embodiments, the phase-transformation layer includes 10-100 vol. % zirconium oxide (ZrO₂). The phase-transformation layer may comprise up to 10 vol. % of one or more phases of a different metal oxide, which can be incorporated into the phase-transformation layer to affect, for example, optical properties of the layer such as refractive index. The additional phase may comprise aluminum oxide or other suitable material. The additional phase may be insoluble in the parent zirconia phase, and may be distributed homogenously (e.g. a dispersion of mixed grains) or heterogeneously (e.g., in layers or strata).

Zirconium oxide may be pure ZrO₂ or, optionally, zirconium oxide that is stabilized by a dopant such as yttrium, calcium, magnesium, cesium, or combinations thereof A dopant can be incorporated into the phase-transformation layer to stabilize a metastable phase of zirconium oxide.

In embodiments, the phase-transformation layer can be provided to improve the apparent scratch resistance of a substrate, such as an ion-exchange-strengthened cover glass, against visible scratches. Without wishing to be bound by theory, this can be achieved by (i) simultaneously increasing the effective hardness of the glass substrate surface relative to an uncoated glass substrate, which beneficially minimizes scratch dimensions under a given load, and (ii) providing a layer material that undergoes a volume-increasing, stress-induced phase-transformation during a scratch event.

The phase-transformation layer may comprise one or more phases of zirconium oxide. Zirconium oxide exhibits three equilibrium polymorphs: monoclinic to ˜1100° C., tetragonal to 2370° C., and cubic up to the melting point of 2680° C.

By appropriate deposition processing to control crystallite grain size and morphology, a phase-transformation layer comprising the metastable tetragonal phase can be formed on a glass substrate. This tetragonal phase exhibits a tetragonal-to-monoclinic transformation in response to an applied stress or associated strain field, and can lead to a significant “upward” surface deformation, i.e., away from the substrate.

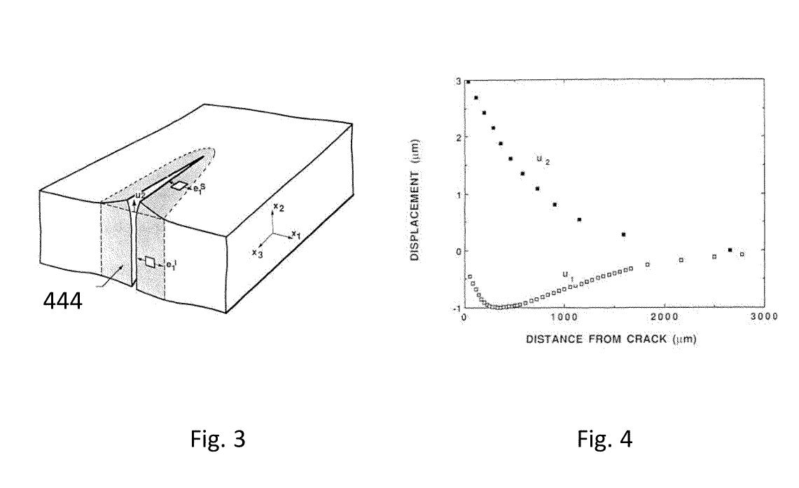

FIG. 3 illustrates for a crack propagating in zirconium oxide the observed surface displacement due to the tetragonal-to-monoclinic phase transformation. A phase-transformation zone 444 is formed proximate to the crack. Referring also to FIG. 4, which is a plot of displacement versus distance from the crack tip, this example shows micron-scale upward displacement at a free surface of the material adjacent to the crack. The displacement extends significantly in the lateral dimension away from the crack.

This phase transformation described above may have an accompanying volumetric expansion. If constrained on all sides, such as at the tip of a microcrack, the phase transformation can induce a compressive stress. Incorporated into a thin film and with the phase transformation occurring at a free surface within a shallow scratch groove, the expansion according to present embodiments is intended to yield an upward surface deformation that effectively reduces scratch depth and alters its cross-sectional contour. This effect can reduce the visibility of the groove via its angular light-scattering behavior. Thus, scratch-resistance can be provided with a single phase-transformation layer. In the zirconium oxide system, the phase transformation from the tetragonal polymorph to the monoclinic polymorph is accompanied by a volume expansion of 3% to 5%.

The phase-transformation layer may be further characterized by its chemical, mechanical and/or optical properties. According to various embodiments, a scratch-resistant, surface-modified glass substrate may possess an array of properties, which may include low weight, high impact resistance, and high optical transparency.

In embodiments the phase-transformation layer is suitably adhered to the underlying glass substrate so as to not delaminate or peel during use. In embodiments where the phase-transformation layer is in direct physical contact with the glass substrate, the adhesion between the layer and the glass substrate can be characterized by an interfacial energy in the range of 10 to 100 J/m² or more, e.g., greater than 100 or 150 J/m². Surface treatments to enhance adhesion may also be used, such as pre-cleaning, pre-sputtering, acid-etching, roughening, or other such treatment.

One attribute of the phase-transformation layer can be chemical resistance. As an outward-facing layer, insolubility of the phase-transformation layer in common solvents such as water, salt water, ammonia, isopropyl alcohol, methanol, acetone and other commercial cleaning solutions can extend the durability and lifetime of the layer. It may also be beneficial if the phase-transformation layer is resistant to degradation due to exposure to ambient lighting including ultra-violet light. In embodiments, the layer exhibits no appreciable yellowing due to light exposure after 1000 hours or after 10000 hours.

A thickness of the phase-transformation layer can range from 10 nm to 2 microns. For example, the average layer thickness can be about 10, 20, 50, 100, 200, 300, 400, 500, 600, 700, 800, 900, 1000, 1500 or 2000 nm. In embodiments, a thickness of the phase-transformation layer can range from 50 to 200 nm.

The phase-transformation layer can have a hardness that is greater than (e.g., at least 10% greater than) the hardness of the glass substrate. For instance, the layer hardness can be at least 10, 20, 30, 40 or 50% greater than the substrate hardness. An example phase-transformation layer can have a Berkovich indenter hardness for an indentation that is shallower than 100 nm of at least 10 GPa, e.g., a Berkovich indenter hardness of between 10 and 30 GPa.

A Young's modulus of the phase-transformation layer can be in the range of 50 to 200 GPa, e.g., from 60 to 100 GPa or from 100 to 200 GPa. In further embodiments, a Young's modulus of the phase-transformation layer can be greater than 200 GPa.

In embodiments, the phase-transformation layer is a non-porous, dense or substantially-dense layer. With respect to its theoretical density, the phase-transformation layer can have a relative density of at least 70%, e.g., at least 80% or 90%. In embodiments, the density of the phase-transformation layer is from about 70-90% of its theoretical density. In further embodiments, the density of the phase-transformation layer is from about 97-100% of its theoretical density.

The phase-transformation layer is a polycrystalline layer. A polycrystalline layer may comprise equiaxed crystal grains. Within the layer, the plurality of grains may be randomly oriented or have a preferred orientation.

Polycrystalline layers may be characterized by their grain size. In embodiments, the average grain size in a polycrystalline phase-transformation layer can be less than 1 micron. In further embodiments, the grain size is less than 50, 20, 10, 5, 2 or 1 nm and can include grain dimensions over a range of any of the foregoing values, e.g., from about 1 nm to 1 micron or from about 5 nm to 50 nm. A zirconium oxide phase-transformation layer, for example, may comprise tetragonal zirconium oxide having an average grain size of from 2 to 10 microns, e.g., about 6 microns.

The phase-transformation layer can be CTE-matched with the glass substrate. In embodiments, the phase-transformation layer has a coefficient of thermal expansion that differs from the coefficient of thermal expansion of the glass substrate by at most 10 ppm, the CTE difference is less than 10 or 5 ppm. In embodiments, a difference in the coefficient of thermal expansion between the phase-transformation layer and the glass substrate is between 5 and 10 ppm.

The phase-transformation layer can be under a state of compressive stress. A slightly compressive stress can improve resistance to crack propagation within or through the layer. In embodiments where the layer is under a state of compressive stress, an absolute value of the stress (which is conventionally negative for compression and positive for tension) can be between 10 and 500 MPa.

The phase-transformation layer may, according to some embodiments, have a coefficient of friction in the range of 0.1 to 0.8, e.g., 0.1 to 0.3 or 0.3 to 0.8. Example coefficient of friction values for the layer include 0.1, 0.2, 0.3, 0.4, 0.5, 0.6, 0.7 and 0.8.

The outward-facing surface of the phase-transformation layer can be textured but, in embodiments, the outward-facing surface is a smooth, planar surface that may be characterized by a root-mean-square (rms) roughness over an area of 1 μm² of less than 100 nm, e.g., from 5 to 100 nm. In embodiments the rms surface roughness of the layer is less than 5 nm.

As noted above, the phase-transformation layer may be provided directly onto a surface of the glass substrate. Alternatively, the layer may be provided onto a previously surface-modified glass substrate. If included, one or more intervening layers between the phase-transformation layer and the glass substrate may include an anti-reflective layer, an anti-sparkle layer, an anti-glare layer and an adhesion-promoting layer.

The optical properties of the phase-transformation layer can be tailored to minimize scattering and absorption of light, which can result in a high optical-quality glass article. In applications where the glass substrate is used as display cover glass, the phase-transformation layer can be optically clear (e.g., water clear) and optically transparent. For example, the phase-transformation layer can have a refractive index within the visible spectrum of less than about 3, e.g., from about 1.4 to 2, from about 1.45 to 1.55, or from about 1.7 to 2.8, and a reflectance within the visible spectrum of less than 40%, e.g., less than 40, 30, 20, 10 or 5%. The refractive index of the phase-transformation layer can be substantially equal to the refractive index of the glass substrate.

In embodiments, the phase-transformation layer can transmit greater than 70% of incident light, e.g., at least 70% or 80%. For instance, the layer can transmit between 80 and 90% of incident light. In further embodiments, the phase-transformation layer can transmit 95% or more of incident light, e.g., at least 95, 96, 97, 98 or 99%. A water clear layer transmits greater than 98% of incident light.

In addition to the optical transparency of the phase-transformation layer, which can facilitate its use within a display glass cover, the phase-transformation layer can be transparent to radio frequencies. In embodiments, the radio frequency (RF) transparency of the phase-transformation layer can be at least 50%. For example, the RF transparency of the layer can be 50, 60, 70, 80, 90 or 95%. The phase-transformation layer can be substantially free of scratches, including microductile scratches.

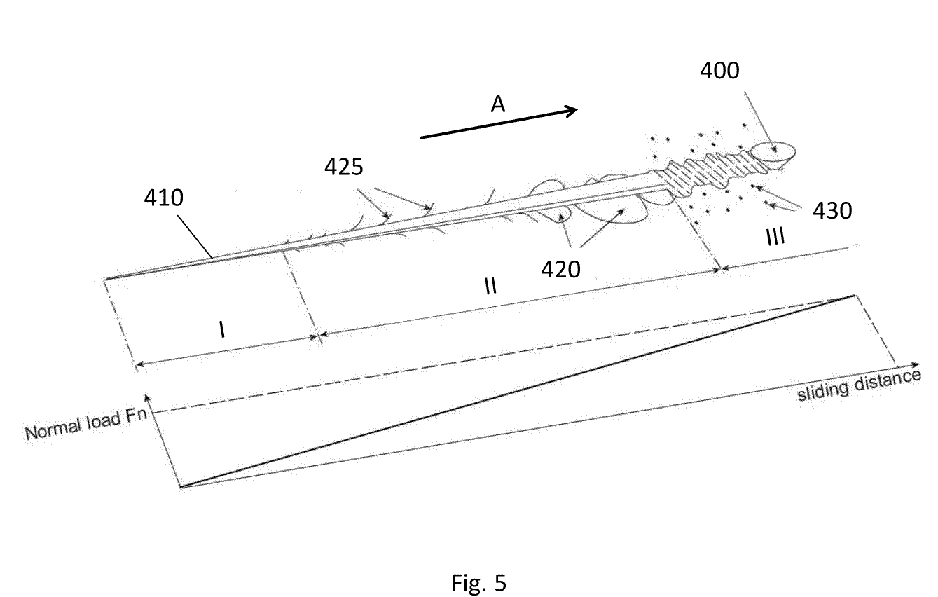

The loading cycle applied during scratch-resistance testing typically gives rise to three different response regimes. The scratch pattern made on a glass surface as a function of applied load is shown schematically in FIG. 5. Arrow A in FIG. 5 indicates the direction of scratching. The first regime is the micro-ductile regime (I), which corresponds to plastic deformation under the indenter 400 and the appearance of a permanent groove 410. In this first regime, damage or debris on either side of the groove may also appear. A characteristic of the micro-ductile regime is the absence of sub-surface lateral cracks 410. The second regime (II), which is encountered when the load increases, is called the micro-cracking regime. Chip and fragment 420 formations occur in the micro-cracking regime as a consequence of the intersection of lateral cracks with the surface. Radial (chevron) cracks 425 may also form in the micro-cracking regime. Such cracking can dramatically affect the optical transparency of the glass. The third regime (III) is termed the micro-abrasive regime, and is characterized by the formation of bulk debris 430.

In particular, optical data indicates that scratch visibility for cover glass articles in the off-state (dark-field viewing mode) is principally attributed to microductile grooves, especially in glasses with high intrinsic damage resistance.

Further optical data also indicates that microductile scratches exhibit a certain angular distribution of light scattering that—in contrast to the undamaged glass surrounding a scratch—directs light to off-specular angles, and ultimately leads to detection by the naked eye. In view of the foregoing, Applicants have observed that when the scratch depth is reduced, there is less net scatter and reduced peak scatter, and thus the scratch is less visible at any given off-specular angle under any given lighting condition.

Applicants have also demonstrated that sharper/deeper wall angles defining the contour of a scratch will tend to scatter light further out into off-specular directions, rendering them effectively more visible over a wider angular range and/or further from the specular angle where contrast to a diffuse light source is effectively higher.

In present embodiments, the phrase-transformation layer can effectively alter the scratch contour to reduce visibility of the scratch. Specifically, scratch visibility can be reduced by causing less light to be scattered out to directions further away from the specular angle, and by reducing the peak scatter by altering the angular scatter profile.

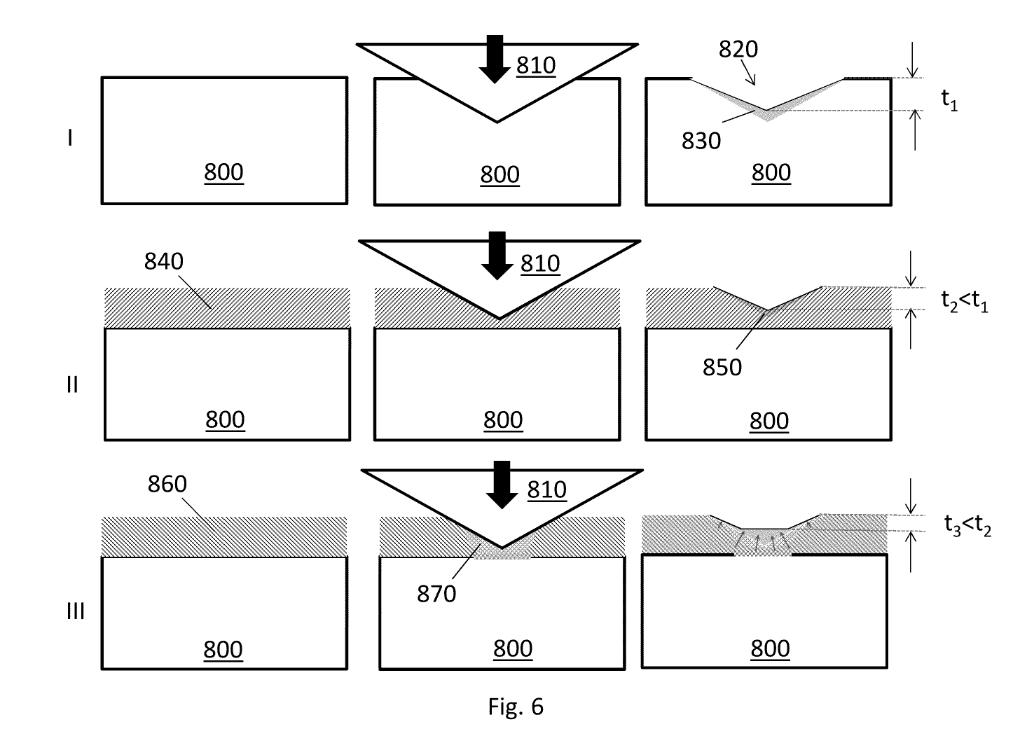

The modeled deformation behavior of the presently-disclosed glass substrate having a phase-transformation layer is depicted in FIG. 6 together with the deformation behavior for an uncoated glass substrate and a glass substrate having a conventional hard coat.

As shown in the top row (I) of FIG. 6, a glass substrate 800 that is uncoated exhibits a specific deformation response to a sharp, hard implement 810 that impinges on the surface at a given load and is dragged for some distance to create a scratch. This is illustrated in cross-section. For a microductile scratch, this deformation response is characterized by a permanent, “plastically” deformed trench, albeit with an elastic recovery zone 830 that is formed when the load is removed. The final scratch 820 is the permanent groove that remains. The final scratch depth t₁ is indicated by the opposing arrows.

Shown in the middle row (II) of FIG. 6 is a conventional hard coating 840 formed over a glass substrate 800. Typically, the hard coating is engineered to provide high hardness and thus high resistance to deformation, as well as a low elastic modulus, which results in less stress for a given amount of deformation, thus improving the elastic recovery. In this way the degree of permanent deformation in the surface is reduced, as scratches are more difficult to create and shallower.

An elastic recovery zone 850 formed in the hard coating 840 is depicted, which results in a final scratch depth t₂ that is less than the scratch depth t₁ for the uncoated glass substrate.

Illustrated in the third row (III) of FIG. 6 is the example of a phase-transformation layer 860 provided on the glass substrate 800. The phase-transformation layer not only enhances hardness, but is also designed to exhibit a volume expansion upon scratching. The pre-scratched phase-transformation layer can comprise or consist essentially of the tetragonal phase of zirconia. Zirconia has a higher hardness than most glasses and is optically transparent.

The hard phase-transformation layer 860 initially limits the degree of deformation, while the subsequent stress-induced, tetragonal-to-monoclinic phase transformation produces an effective degree of volumetric recovery as a result of a scratch event. Specifically, the volumetric recovery can beneficially alter the final contour of the scratch such that the scratch does not scatter light as strongly into off-specular angles, which limits the visibility of the scratch. A phase-transformation region 870 is formed within the phase-transformation layer proximate to the tip of the scratching implement 810. In the example of a phase-transformation initially comprising tetragonal zirconia, the transformed region can comprise the monoclinic polymorph. A concomitant volume expansion within the phase-transformed region is illustrated, which lessens the total volume of the final scratch and results in a scratch depth (t₃) that is less than the scratch depth (t₁) associated with the uncoated glass substrate or the scratch depth (t₂) associated with the glass substrate having the hard coat.

In the examples involving the hard coating and the phase-transformation layer, the underlying glass substrate may or may not be damaged by the scratching implement 810.

For the three foregoing cases, a summary of the scratch event, recovery event, and final result is provided in Table 2.

TABLE 2
Scratch formation and recovery in various glass structures

| | Sample | Scratch Event | Recovery | Result |
|---|---|---|---|---|
| I | Glass only | Baseline | Baseline | Scratch depth t₁ |
| II | Glass + | Reduced initial | Elastic recovery | Scratch depth t₂ < t₁ |
| | conventional | penetration with | comparable to | |
| | hard coat | respect to baseline | baseline | |
| III | Glass + phase- | Reduced penetration | Elastic recovery | Scratch depth t₃ < t₂, |
| | transformation | with respect to | comparable to | with reduced |
| | layer | baseline and | baseline + phase- | scratch visibility |
| | | formation of phase- | transformation | through volume- |
| | | transformation zone | induced volume | expansion induced |
| | | | expansion | alteration of final |
| | | | | scratch contour |

Technologies that incorporate glass articles that may benefit from scratch resistance include military and civilian optics, including watch crystals, scanner windows at grocery stores, scanner windows on photocopiers, and LCD screen protectors, hard disk memory surfaces, piston rings in engines, machine tools, and other moving and sliding components.

A mobile electronic device comprising a cover plate, at least a portion of which is transparent, is also disclosed. Such mobile electronic devices include, but are not limited to, mobile communication devices such as personal data assistants, mobile telephones, pagers, watches, radios, laptop computers and notebooks, and the like. As used herein, a “cover plate” refers to a glass sheet or window that covers a visual display. At least a portion of the cover plate is transparent to allow viewing of the display. The cover plate may to some extent be resistant to shock, breakage, and scratching and finds application in those electronic devices where a window having high surface strength, hardness, and scratch resistance is desirable. In one embodiment, the cover plate is touch sensitive. An example cover plate is a glass substrate provided with a phase-transformation layer.

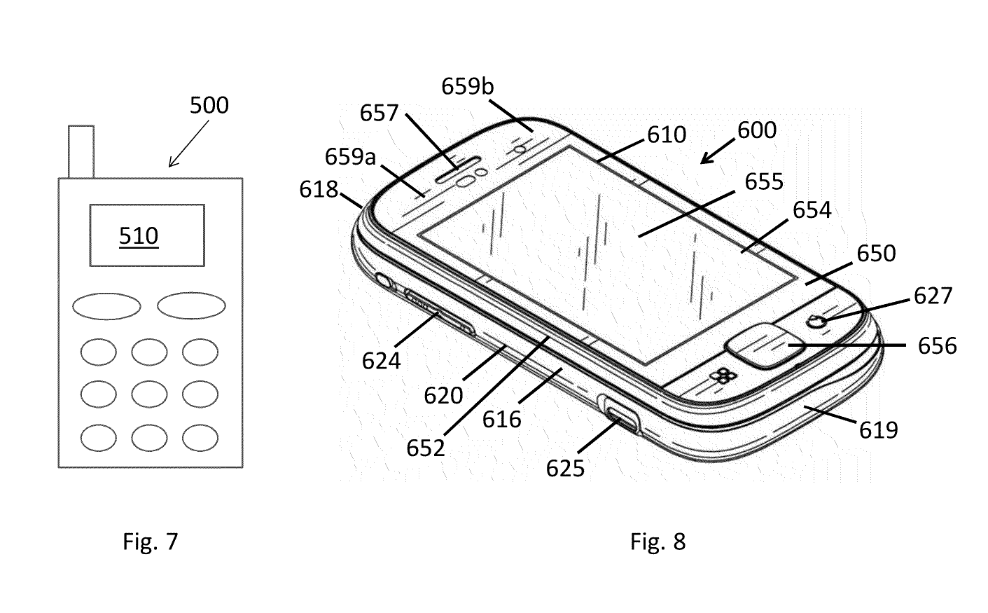

A schematic representation of a top view of a mobile telephone is shown in FIG. 7. Mobile telephone 500 includes a cover plate 510 comprising a surface-modified glass substrate as described herein. In mobile telephone 500, cover plate 510 serves as a display window. During formation of the cover plate, a sheet of down-drawn glass can be cut to the desired shape and size. Before or after sizing the cover plate, the glass sheet may be strengthened by ion exchange, and then provided with an inorganic, scratch-resistant phase-transformation layer over an exposed surface of the glass. The cover plate may then be joined to the body of the mobile electronic device using an adhesive or other means known in the art.

A cover plate for a device such as, but not limited to, the mobile electronic devices described above as well as non-electronic watches and other like, is also provided. The cover plate may be formed from any of the glass compositions disclosed herein above.

Presently-disclosed embodiments also relate to a housing for an electronic device. In embodiments, an electronic device housing can have one or more outer members (e.g., exposed major surfaces), such as front or back surfaces, that are formed of glass. The one or more glass surfaces can be part of outer member assemblies that can be secured to other portions of the electronic device housing.

As an electronic device housing, one embodiment can, for example, include at least a front glass cover placed and secured to provide a front surface for the electronic device enclosure and a back glass cover placed and secured to provide a back surface for the electronic device enclosure.

As shown in FIG. 8, electronic device 600 includes an outer periphery member 620 that surrounds the periphery of electronic device 600 to define some or all of the outer-most side, top, and bottom surfaces (e.g., surfaces 610, 616, 618 and 619) of the electronic device. Outer periphery member 620 can have any suitable shape, and can enclose an inner volume of the device in which electronic device components can be assembled and retained.

In some embodiments, outer periphery member 620 can include one or more openings, knobs, extensions, flanges, chamfers, or other features for receiving components or elements of the device. The features of the outer periphery member can extend from any surface of the outer periphery member, including for example from internal surfaces or from external surfaces. In particular, outer periphery member 620 can include a slot or opening 624 for receiving a card or tray. Opening 624 can be aligned with one or more internal components operative to receive and connect to an inserted component (e.g., an inserted SIM card). As another example, outer periphery member 620 can include connector opening 625 (e.g., for a 30-pin connector) through which a connector can engage one or more conductive pins of electronic device 600. Further, outer periphery member 620 can include opening 627 for providing audio to a user (e.g., an opening adjacent to a speaker), or receiving audio from a user (e.g., an opening adjacent to a microphone).

To retain components within the inner volume, electronic device 600 can include front cover assembly 650 and back cover assembly (not shown) providing the front and back surfaces of the electronic device, respectively. Each cover assembly can be coupled to outer periphery member 620 using any suitable approach, including for example using an adhesive, tape, mechanical fastener, hooks, tabs, or combinations thereof In some embodiments, one or both of cover assemblies can be removable, for example for servicing or replacing electronic device components (e.g., a battery). In some embodiments, cover assemblies can include several distinct parts, including for example a fixed part and a removable part.

In the illustrated example, front cover assembly 650 can include support structure 652 on which glass substrate 654 is assembled. Support structure 652 can include one or more openings, including an opening through which display 655 can be provided. In some embodiments, support structure 652 and glass substrate 654 can include openings for device components, such as button opening 656 and receiver opening 657.

The glass substrate 654 can include a surface-modified glass substrate as disclosed herein. By way of example, the housing can include one or both of a front outer glass substrate that provides a front surface for the housing (as shown) and a back glass substrate that provides a back surface for the housing. The electronic device can be portable and in some cases handheld.

In some embodiments, glass substrate 654 can include a cosmetic finish hiding from view internal components of the electronic device. For example, an opaque layer can be applied to peripheral regions of the glass substrate surrounding display 655 to hide from view the non-display portions of the display circuitry. Because one or more sensors may receive signals through glass substrate 654, the opaque layer can be selectively removed, or selected to allow signals to pass through the glass plate to the sensor behind the plate. For example, glass substrate 654 can include regions 659a and 659b through which sensors (e.g., a camera, infrared sensor, proximity sensor, or ambient light sensor) can receive signals.

As used herein, the singular forms “a,” “an” and “the” include plural referents unless the context clearly dictates otherwise. Thus, for example, reference to a “layer” includes examples having two or more “layers” unless the context clearly indicates otherwise.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

It is also noted that recitations herein refer to a component being “configured” or “adapted to” function in a particular way. In this respect, such a component is “configured” or “adapted to” embody a particular property, or function in a particular manner, where such recitations are structural recitations as opposed to recitations of intended use. More specifically, the references herein to the manner in which a component is “configured” or “adapted to” denotes an existing physical condition of the component and, as such, is to be taken as a definite recitation of the structural characteristics of the component.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a glass substrate that comprises a glass material include embodiments where a glass substrate consists of a glass material and embodiments where a glass substrate consists essentially of a glass material.

It will be apparent to those skilled in the art that various modifications and variations can be made to the present disclosure without departing from the spirit and scope of the invention. Since modifications combinations, sub-combinations and variations of the disclosed embodiments incorporating the spirit and substance of the invention may occur to persons skilled in the art, the invention should be construed to include everything within the scope of the appended claims and their equivalents.

What is claimed is:

1. A glass substrate, comprising:
a glass main body having opposing major surfaces; and
a phase-transformation layer provided over a majority of a first major surface.

2. The glass substrate according to claim 1, wherein the phase-transformation layer comprises ZrO₂, Ln₂O₃, 2CaO.SiO₂, NiS or LuBO₃.

3. The glass substrate according to claim 1, wherein the phase-transformation layer comprises tetragonal zirconia.

4. The glass substrate according to claim 1, wherein the phase-transformation layer comprises at least 10 vol. % tetragonal zirconia.

5. The glass substrate according to claim 1, wherein the phase-transformation layer comprises stabilized tetragonal zirconia.

6. The glass substrate according to claim 1, wherein the phase-transformation layer has an average grain size of less than 1 micron.

7. The glass substrate according to claim 1, wherein the phase-transformation layer has an average grain size of less than 20 nm.

8. The glass substrate according to claim 1, wherein the phase-transformation layer further comprises an aluminum oxide phase.

9. The glass substrate according to claim 1, wherein the phase-transformation layer has a Berkovich indenter hardness ranging from 10 GPa to 30 GPa.

10. The glass substrate according to claim 1, wherein the phase-transformation layer has an optical transparency of at least 70%.

11. The glass substrate according to claim 1, wherein the phase-transformation layer has a thickness ranging from 10 nm to 2000 nm.

12. The glass substrate according to claim 1, wherein the phase-transformation layer is a contiguous layer.

13. The glass substrate according to claim 1, wherein the phase-transformation layer is provided in direct physical contact with the glass substrate.

14. The glass substrate according to claim 1, wherein the phase-transformation layer has a refractive index of less than about 3 at visible wavelengths.

15. The glass substrate according to claim 1, wherein the phase-transformation layer has a reflectance of less than about 40% at visible wavelengths.

16. The glass substrate according to claim 1, wherein the phase-transformation layer is water clear.

17. The glass substrate according to claim 1, wherein the glass substrate has a thickness ranging from about 100 microns to 5 mm.

18. The glass substrate according to claim 1, wherein the glass substrate comprises chemically-strengthened glass.

19. The glass substrate according to claim 1, wherein the first major surface is substantially planar.

20. An electronic device housing, comprising:
at least one of (a) a front glass cover placed and secured to provide a front surface for the electronic device enclosure, and (b) a back glass cover placed and secured to provide a back surface for the electronic device enclosure, wherein the front glass cover and the back glass cover comprise the glass substrate according to claim 1.
